(19) United States
(12) Patent Application Publication
(10) Pub. No.: US 2010/0019374 A1
(43) Pub. Date: Jan. 28, 2010

(54) BALL GRID ARRAY PACKAGE

(75) Inventor: Michael J. Hundt, Double Oak, TX (US)

Correspondence Address: STMICROELECTRONICS, INC., MAIL STATION 2346, 1310 ELECTRONICS DRIVE, CARROLLTON, TX, 75006, US

(73) Assignee: STMICROELECTRONICS, INC., Carrollton, TX (US)

(21) Appl. No.: 12/180,003

(22) Filed: Jul. 25, 2008

(51) Int. Cl. H01L 23/488

(52) U.S. Cl. 257/693; 257/E23.023

(57) ABSTRACT

A thermally conductive ball grid array (BGA) package for integrated circuits having improved ground path employs a printed circuit substrate. The substrate has an array of solder balls disposed on the bottom side. There is an opening in the substrate corresponding to the integrated circuit die. A grounding ring covers the vertical walls of the opening and includes an upper ground collar on the top side of the substrate and a lower ground collar on the bottom side of the substrate. A thermally and electrically conductive heat spreader is attached to the lower ground collar on the bottom side of the BGA package, covering the opening in the substrate. The integrated circuit die is mounted on the heat spreader, with the active side up, within the opening in the substrate. Ground pads on the active side of the die are attached to the upper ground collar by wire bonds, to provide a continuous ground path from the ground pads to the heat spreader. Molded plastic covers the semiconductor device and the top side of the substrate.

### FIELD OF THE INVENTION

The present invention relates generally to semiconductor integrated circuit device packages, and is more particularly directed to ball grid array packages incorporating thermal conduction techniques.

### BACKGROUND

Integrated circuits packaged in the ball grid array (BGA) format are widely used in modern electronic devices. Conventional BGA packages are similar in layout and arrangement to pin grid array (PGA) packages, providing a rectangular or square array of connections on the underside of the integrated circuit package, however, BGA packages provide a much denser arrangement of the connections. In place of the pin connectors used in PGA packages, BGA packages utilize a solder ball located at each connector location. The BGA package is attached to a printed circuit board by reflowing the solder balls to make connection to conductors at the surface of the printed circuit board. BGA packages are self-aligning, as the surface tension of the solder pulls the BGA package into proper alignment with the corresponding conductors on the printed circuit board. As computers, cell phones, personal digital assistants (PDA) and other electronic systems continue to become smaller and lighter, the amount of heat generated, and accordingly the amount of heat needed to be dissipated has increased accordingly. Many of the traditional techniques for heat removal available for large-scale computer systems, such as the use of fans for convection cooling of the integrated circuits, are not applicable in these small devices. Therefore, many modern systems utilize thermal conduction as the primary mode of heat removal from the integrated circuits in the system.

In addition, the increased performance and complexity of modern integrated circuits also increases the pressure on the grounding system used in conventional BGA packages. Many prior art integrated circuits are grounded through the backside of the die, but there is also a need to provide a ground connection to the active side of the die. Traditional routing of the ground path through the solder ball connections does not provide sufficient performance.

### BRIEF DESCRIPTION OF THE FIGURES

The accompanying figures, where like reference numerals refer to identical or functionally similar elements throughout the separate views and which together with the detailed description below are incorporated in and form part of the specification, serve to further illustrate various embodiments and to explain various principles and advantages all in accordance with the present invention.

FIGS. 1 and 1(a) are cross sectional views of a BGA package in accordance with some embodiments of the invention.

FIG. 2 is an isometric view of the top side of a substrate for a BGA package in accordance with some embodiments of the invention.

FIG. 3 is an isometric view of the bottom side of a substrate for a BGA package in accordance with some embodiments of the invention.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION

Before describing in detail embodiments that are in accordance with the present invention, it should be observed that the embodiments reside primarily in combinations of components related to ball grid arrays with enhanced ground path and thermal conduction. Accordingly, the apparatus components and methods have been represented where appropriate by conventional symbols in the drawings, showing only those specific details that are pertinent to understanding the embodiments of the present invention so as not to obscure the disclosure with details that will be readily apparent to those of ordinary skill in the art having the benefit of the description herein.

In this document, relational terms such as first and second, top and bottom, and the like may be used solely to distinguish one entity or action from another entity or action without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “comprises . . . a” does not, without more constraints, preclude the existence of additional identical elements in the process, method, article, or apparatus that comprises the element.

Further, it is expected that one of ordinary skill, notwithstanding possibly significant effort and many design choices motivated by, for example, available time, current technology, and economic considerations, when guided by the concepts and principles disclosed herein will be readily capable of generating such BGA packages with minimal experimentation.

A thermally conductive ball grid array (BGA) package for integrated circuits having improved ground path employs a printed circuit substrate. The substrate has an array of solder balls disposed on the bottom side. There is an opening in the substrate corresponding to the integrated circuit die. A grounding ring covers the vertical walls of the opening and includes an upper ground collar on the top side of the substrate and a lower ground collar on the bottom side of the substrate. A thermally and electrically conductive heat spreader is attached to the lower ground collar on the bottom side of the BGA package, covering the opening in the substrate. The integrated circuit die is mounted on the heat spreader, with the active side up, within the opening in the substrate. Ground pads on the active side of the die are attached to the upper ground collar by wire bonds, to provide a continuous ground path from the ground pads to the heat spreader. Molded plastic covers the semiconductor device and the top side of the substrate.

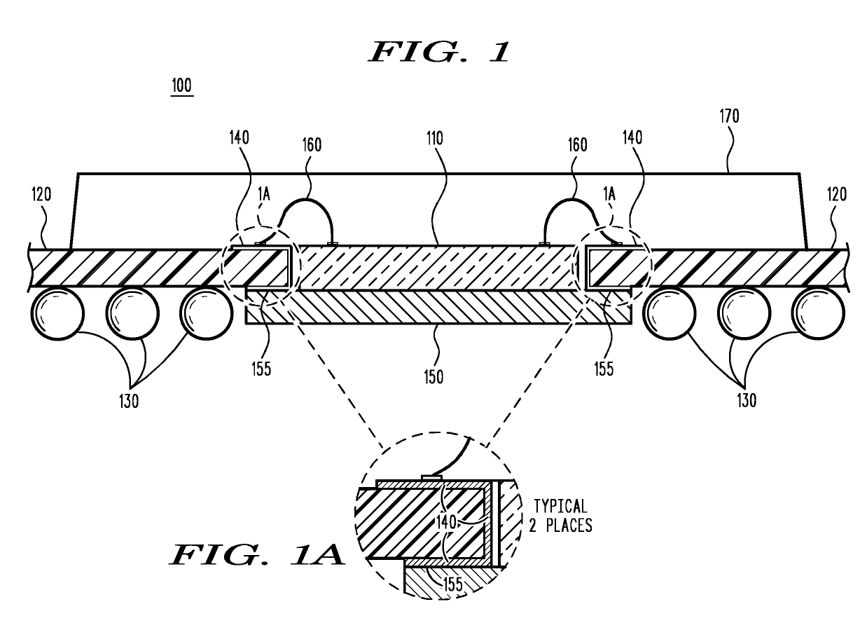

Referring now to FIGS. 1, 1(a), 2, and 3, a BGA package 100 contains an integrated circuit die 110, which is a solid-state semiconductive device such as a microprocessor, memory device, logic device, analog device or other integrated circuit, as is well known in the art. Package 100 is based on a circuit carrying insulating substrate 120 that consists of a dielectric substrate such as a glass reinforced polymer, flexible polymer, ceramic, or other BGA substrates familiar to one of ordinary skill in the art. The substrate 120 has a plurality of circuit traces 210 on a top side 215 that serve to conduct electrical signals. These circuit traces generally consist of runners and bond pads. On the bottom side 315 lies an array of surface mount pads 320, in any of a variety of patterns and shapes. These surface mount pads 320 are electrically connected to respective portions of the circuit traces 210 on the top side 215 by vias 225 that are plated to extend vertically through the substrate 120 in conventional manner. A solder ball 130 or bump is situated on each of the individual surface mount pads 320. Thus, a continuous electrical connection is formed between the circuit traces 210 on the top side of the substrate and the solder balls 130 on the bottom side. The circuit carrying insulating substrate 120 additionally has an opening 230 disposed therein, typically in a central portion of the top side 215, that generally corresponds to the size and shape of the integrated circuit die 110. The opening 230 is sufficiently sized to allow the integrated circuit die 110 to be comfortable positioned within. A grounding ring 140 comprises metal plating on the vertical perimeter walls 235 of the opening 230, on the top side 215 of the substrate around the periphery of the opening, and likewise on the bottom side 315 around the periphery of the opening. The metal is typically plated in a manner similar to that used to plate the vias 225. Thus, in one embodiment, the grounding ring 140 resembles an extremely large plated through hole, except that comprises a size and shape to accommodate the integrated circuit die 110. A clear understanding of the structure of the grounding ring 140 can be determined by simultaneous inspection of FIGS. 1, 2, and 3, where one sees the cross section, the upper surface and the lower surface of the grounding ring. The upper ground collar 240 around the periphery of the opening is of a metal finish sufficient to accommodate wire bonding, while the lower ground collar 340 is finished to be a solderable surface or other surface that provides good mechanical bonding for a polymeric conductive adhesive.

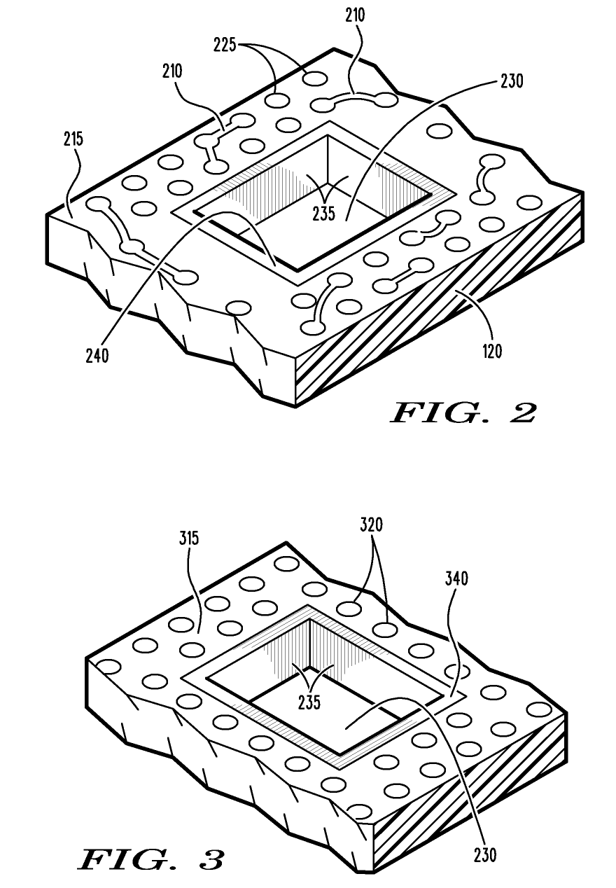

While shown in FIG. 2 as a continuous ring around the opening, an alternate embodiment of our invention envisions that the upper ground collar 240 is a plurality of wire bond pads that are each connected to the plated vertical wall 235 of the grounding ring 140. Likewise, the lower ground collar 340, while depicted in FIG. 3 as a continuous ring around the opening, envisions that the collar is discontinuous. Clearly, the shape and size of both the upper and lower ground collars can be varied to suit individual design parameters, and still fall within the scope and spirit of our invention.

Referring back to FIGS. 1 and 1(a), a heat spreader 150, formed of a material with high thermal conductivity and high electrical conductivity, is attached 155 to the lower ground collar on the bottom side of the substrate. The mechanism of the heat spreader attachment should be sufficient to provide mechanical bonding to the substrate, electrical connection to the grounding ring 140, and thermal conductivity to the grounding ring. Soldering the heat spreader to the lower collar is one means of attachment that provides these features, as are conductive adhesives. Conductive adhesives are generally considered to be either electrically conductive or thermally conductive, however adhesives for this attachment should provide both electrical and thermal conductivity, along with mechanical bonding. One embodiment of our invention utilizes a copper slug as the heat spreader, but other materials known in the art to be thermally and electrically conductive may alternatively be used. Copper slugs can be readily formed, and exhibit good solderability and good bonding with adhesives. Obviously, one may wish to provide any of various plated surfaces such as tin or nickel on either or both faces of the slug to enhance the soldering. The integrated circuit die 110 is then mounted to the top surface of the heat spreader 150 so that the inactive side is facing the heat spreader. The die is held in place by conventional die attach techniques, such as a conductive epoxy or eutectic mount. With the active surface containing the bond pads facing upwards, bond wires 160 are then attached between those bond pads on the die that are ground connections and the upper ground collar 240 of the grounding ring 140. Generally, a plurality of wire bonds will span between the die and the grounding ring to insure a good ground path from the die to the heat spreader. Inspection of FIG. 1 will reveal that a continuous ground path from the integrated circuit die is formed by a combination of the wire bonds 160, the grounding ring 140, and the heat spreader 150.

Upon completion of the wire bond process, an encapsulant 170 is formed over the integrated circuit die 110, wire bonds 160, and at least portions of the top side 215 of the substrate 120 in conventional manner. In the example of FIG. 1, encapsulate 170 is formed by transfer molding; alternatively, the encapsulant may be “globbed” over the integrated circuit die and substrate by dispensation and curing.

When the completed BGA package is soldered to a system circuit board, the heat spreader is also soldered to ground connections on the system circuit board. Design of the system circuit board will provide excellent ground connection to the BGA along with good thermal conductivity to dissipate heat from the die.

In the foregoing specification, specific embodiments of the present invention have been described. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention. The benefits, advantages, solutions to problems, and any element(s) that may cause any benefit, advantage, or solution to occur or become more pronounced are not to be construed as a critical, required, or essential features or elements of any or all the claims. The invention is defined solely by the appended claims including any amendments made during the pendency of this application and all equivalents of those claims as issued.

What is claimed is:

1. A ball grid array package, comprising:
an integrated circuit die having ground and signal pads on a first surface thereof;
a printed circuit substrate having a metallization pattern formed on a first side, and having disposed on a second opposing side an array of solder balls in electrical contact with respective portions of the metallization pattern;
an opening in the printed circuit substrate extending from the first side to the second side, approximately corresponding to the integrated circuit die;
a grounding ring formed about a perimeter of the opening comprising metallization on the vertical walls of the opening electrically connected to one or more wire bond pads on the first side of the substrate and electrically connected to one or more attachment pads on the second side of the substrate;
a thermally and electrically conductive heat spreader attached to the one or more attachment pads sufficient to provide electrical and mechanical connection to the grounding ring;
the integrated circuit die situated in the opening and mounted on the heat spreader;
wire bonds connecting the integrated circuit die ground pads to the grounding ring by one or more wire bond pads, to provide electrical connection from the ground pads to the heat spreader; and
a protective cover formed over the integrated circuit die, the wire bonds, and at least portions of the first side of the printed circuit substrate.

2. The ball grid array package as described in claim 1, further comprising a solderable surface on a side of the heat spreader opposite to the side of the heat spreader attached to the one or more attachment pads, for soldering to an electrical ground in a mother board.

3. The ball grid array package as described in claim 2, wherein the solder balls and the solderable surface are soldered to the mother board.

4. The ball grid array package as described in claim 1, wherein the heat spreader comprises copper.

5. The ball grid array package as described in claim 1, wherein the heat spreader is attached by conductive adhesive.

6. The ball grid array package as described in claim 1, wherein the heat spreader is attached by solder.

7. The ball grid array package as described in claim 1, wherein the protective cover is molded plastic.

8. The ball grid array package as described in claim 2, wherein a plane formed by the solderable surface lies above a plane formed by the bottom of the solder balls.

9. The ball grid array package as described in claim 1, wherein the grounding ring is plated metal.

10. A ball grid array package, comprising:
a semiconductor device having ground pads on an active side;
a circuit carrying insulating substrate having an array of solder balls disposed on a bottom side;
an opening situated in the substrate, corresponding to the semiconductor device;
a grounding ring, formed in the opening, comprising an upper ground collar formed on a top side of the substrate about a perimeter of the opening, connected to an interconnect ring formed on a vertical wall of the opening, and connected to a lower ground collar formed on the bottom side of the substrate about the perimeter of the opening;
a slug, comprised of a thermally and electrically conductive material, electrically and mechanically attached to the lower ground collar so as to cover the opening;
the semiconductor device situated in the opening and mounted on the slug;
wire bonds connecting the semiconductor device ground pads to the upper ground collar; and
a protective cover over the semiconductor device and the top side of the substrate.

11. The ball grid array package as described in claim 10, further comprising a solderable surface on a side of the slug opposite to the side of the slug attached to the lower ground collar, suitable for soldering to an electrical ground in a mother board.

12. The ball grid array package as described in claim 11, wherein the solder balls and the solderable surface are soldered to the mother board.

13. The ball grid array package as described in claim 10, wherein the slug comprises copper.

14. The ball grid array package as described in claim 10, wherein the slug is attached by conductive adhesive.

15. The ball grid array package as described in claim 10, wherein the slug is attached by solder.

16. The ball grid array package as described in claim 10, wherein the protective cover is molded plastic.

17. The ball grid array package as described in claim 11, wherein a plane formed by the solderable surface lies above a plane formed by the bottom of the solder balls.

18. The ball grid array package as described in claim 10, wherein the grounding ring is plated metal.
